(19) United States
(12) Patent Application Publication
(10) Pub. No.: US 2014/0048129 A1
(43) Pub. Date: Feb. 20, 2014

(54) SOLAR CELL AND FABRICATING METHOD THEREOF

(71) Applicant: AU OPTRONICS CORPORATION, Hsin-Chu (TW)

(72) Inventors: Tsung-Pao CHEN, HSIN-CHU (TW); Shih-Hsien YANG, HSIN-CHU (TW); Yu-Chun CHEN, HSIN-CHU (TW); Ming-Hui CHIU, HSIN-CHU (TW); Yi-Hsuan LIN, HSIN-CHU (TW); Yen-Cheng HU, HSIN-CHU (TW); Jen-Chieh CHEN, HSIN-CHU (TW); Zhen-Cheng WU, HSIN-CHU (TW)

(73) Assignee: AU OPTRONICS CORPORATION, HSIN-CHU (TW)

(21) Appl. No.: 13/792,485

(22) Filed: Mar. 11, 2013

(30) Foreign Application Priority Data
Aug. 16, 2012 (CN) 201210292352.X

(51) Int. Cl. H01L 31/0352

(52) U.S. Cl. CPC H01L 31/035281
USPC 136/256; 438/72

(57) ABSTRACT

A solar cell includes a substrate. The substrate has a light-receiving surface and a back surface opposite to the light-receiving surface. The substrate includes plural trenches formed on the back surface. The solar cell includes plural n-type diffusion areas and plural p-type diffusion areas alternately disposed on the back surface and the surface of the trenches. The possibility of recombination of the electron-hole pair while moving can be reduced because of the trenches, which are formed in the substrate.

### RELATED APPLICATIONS

This application claims priority to China Application Serial Number 201210292352.X, filed Aug. 16, 2012, which is herein incorporated by reference.

### BACKGROUND

1. Field of Invention

The present invention relates to a solar cell. More particularly, the present invention relates to a back-contact type solar cell.

2. Description of Related Art

Solar cells are devices that utilize photovoltaic effect of materials to transform environmental photo energy into electric energy. The phenomenon that conductive carriers in materials are generated from the light irradiating the material is called photovoltaic effect. In the semiconductor material, electron-hole pairs are generated from the irradiation of the solar light and the excitation of the electrons in the silicon atoms. These electrons and holes would be affected by an in-built electric potential, such that the electrons and the holes would be attracted by n-type semiconductor and p-type semiconductor respectively and would be gathered at opposite sides. The external surface of the semiconductor material can be connected by electrodes thereby forming a loop.

In order to increase the light capture efficiency of solar cells, back-contact type solar cells are widely utilized. In contrast to the conventional solar cells, where the positive electrodes and the negative electrodes are disposed on opposite sides of the solar cells and the electrons and the holes can move to the opposite electrodes respectively, the back-contact type solar cells have the positive electrodes and the negative electrodes which are disposed at the back surface of the solar cell and thereby elongate a moving path of the electrons and the holes. As such, the electrons and the holes in the back-contact type solar cells are easily recombined during moving, or are captured by the recombination center in the semiconductor material and disappear.

### SUMMARY

The invention provides a solar cell having trenches to keep the generated electron-hole pairs from recombination or being captured during moving.

An aspect of the invention provides a solar cell, which includes a substrate, a front surface field, an antireflection layer, a plurality of n-type diffusion areas and a plurality of p-type diffusion areas. The substrate includes a light-receiving surface, a back surface opposite to the light-receiving surface, and a plurality of trenches disposed on the back surface. The trenches divide the back surface into a plurality of first contact areas and a plurality of second contact areas, and the first contact areas and the second contact areas are alternately arranged. The front surface field is disposed on the light-receiving surface of the substrate. The antireflection layer is disposed on the front surface field. The n-type diffusion areas and the p-type diffusion areas are alternately disposed on the back surface. The n-type diffusion areas are respectively disposed on a surface of the first contact areas and a part of the trenches connecting to a side of the first contact areas, and the p-type diffusion areas are respectively disposed on a surface of the second contact areas and another part of the trenches connecting to a side of the second contact areas.

A depth of the trenches is equal to or greater than half of a thickness of the substrate. A width of the first contact areas is substantially equal to a width of the second contact areas. The width of the first contact areas and the second contact areas is substantially not smaller than a width of the trenches. The solar cell further includes a plurality of first conductive layers disposed on the first contact areas respectively, and a plurality of second conductive layers disposed on the second contact areas respectively. The first conductive layers and the second conductive layers are coplanarly arranged. The trenches are arranged parallel to each other. The trenches are arranged vertically to the first contact areas and the second contact areas. Opposite sides of each of the first contact areas are respectively connected to a p-type trench and a n-type trench, and opposite sides of each of the first contact areas are respectively connected to the n-type trench and the p-type trench, in which the p-type trench is the trench with p-type diffusion area thereon, and the n-type trench is the trench with n-type diffusion area thereon.

Another aspect of the invention provides a method for fabricating solar cell. A substrate is provided, and the substrate has a light-receiving surface and a back surface opposite to the light-receiving surface. A plurality of trenches are formed on the back surface of the substrate, in which the trenches divide the back surface into a plurality of first contact areas and a plurality of second contact areas, and the first contact areas and the second contact areas are alternately arranged. A plurality of n-type diffusion areas are formed on a surface of the first contact areas and a part of the trenches connecting to a side of the first contact areas. A plurality of p-type diffusion areas are formed on a surface of the second contact areas and another part of the trenches connecting to a side of the second contact areas. A front surface field is formed on the light-receiving surface. An antireflection layer is formed on the front surface field. The trenches are formed on the back surface of the substrate by a laser drilling process or an etching process. A depth of the trenches is equal to or greater than half of a thickness of the substrate. A width of the first contact areas is substantially equal to a width of the second contact areas. The width of the first contact areas and the second contact areas is substantially not smaller than a width of the trenches. The method further includes forming a plurality of first conductive areas on the first conduct areas respectively, and forming a plurality of second conductive areas on the second conductive areas respectively. The first conductive areas and the second conductive areas are coplanarly arranged. The trenches are arranged parallel to each other. The trenches are arranged vertically to the first contact areas and the second contact areas. Opposite sides of each of the first contact areas are respectively connected to a p-type trench and a n-type trench, and opposite sides of each of the first contact areas are respectively connected to the n-type trench and the p-type trench, in which the p-type trench is the trench with p-type diffusion area thereon, and the n-type trench is the trench with n-type diffusion area thereon.

The n-type diffusion areas and the p-type diffusion areas can be extended into the substrate with the design of the trenches. Such that the when an electron-hole pair is generated, the electron or the hole can move toward the n-type diffusion areas or the p-type diffusion areas in a shorter path. The situation of the electron-hole pair recombination during movement or the electron or the hole being captured by a recombination center of the semiconductor substrate can be prevented.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view of an embodiment of a solar cell of the invention; and

FIG. 2A to FIG. 2I are cross-sectional views of a solar cell of different steps of an embodiment of a method for fabricating solar cell of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

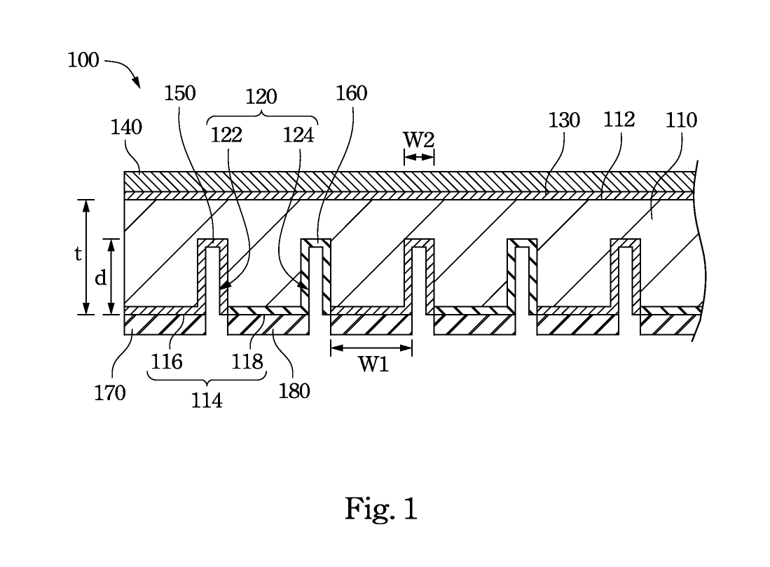

FIG. 1 is a cross-sectional view of an embodiment of a solar cell of the invention. The solar cell 100 is a back-contact type solar cell. The solar cell 100 includes a substrate 110. The substrate 110 has a light-receiving surface 112 and a back surface 114 opposite to the light-receiving surface 114. The light-receiving surface 112 and the back surface 114 are two opposite surfaces of the substrate 11. The substrate 110 further includes a plurality of trenches 120. The trenches 120 divide the back surface 114 into a plurality of first contact areas 116 and a plurality of second contact areas 118. The first contact areas 116 and the second contact areas 118 are alternately arranged, and the adjacent first contact areas 116 and the second adjacent areas 118 are divided by the trenches 120. The trenches 120 are arranged parallel to each other. The trenches 120 are arranged vertically to the first contact areas 116 and the second contact areas 118.

The solar cell 100 includes a front surface field (FSF) 130 disposed on the light-receiving surface 112. The front surface field 130 can be a n-type diffusion layer for helping the solar cell 100 collect more holes in order to reduce the loss due to recombination of electron-hole pairs. The substrate 110 is made of silicon material. In order to reduce the power loss caused by reflection, the solar cell 100 further includes an antireflection layer (ARC) 140 formed on the front surface field 130. The antireflection layer 140 can be a SiN film or a TiO₂ film. The antireflection layer 140 can be optionally disposed with a passivation layer for protecting the surface of the solar cell 100.

The solar cell 100 includes a plurality of n-type diffusion areas 150 and a plurality of p-type diffusion areas 160. The n-type diffusion areas 150 and the p-type diffusion areas 160 are alternately disposed on the back surface 114 of the substrate 110. The n-type diffusion areas 150 are respectively disposed on the surface of the first contact areas 116 and a part of the trenches 120 connecting to a side of the first contact areas 116. The p-type diffusion areas 160 are respectively disposed on the surface of the second contact areas 118 and another part of the trenches 120 connecting to a side of the second contact areas 118. Namely, the trenches 120 can be regarded as including plural n-type trenches 122 with n-type diffusion areas 150 thereon, and plural p-type trenches 124 with p-type diffusion areas 160 thereon. Two opposite sides of each of the n-type trenches 122 are respectively connected the first contact area 116 and the second contact area 118. Twp opposite sides of each of the p-type trenches 124 are respectively connected to the second contact area 118 and the first contact area 116. Two opposite sides of the first contact areas 116 are respectively connected to the n-type trench 122 and the p-type trench 124. Two opposite sides of the second contact areas 118 are respectively connected to the p-type trench 124 and the n-type trench 122. The n-type diffusion areas 150 are respectively disposed on the surface of the first contact areas 116 and the adjacent n-type trenches 122. The p-type diffusion areas 160 are respectively disposed on the surface of the second contact areas 118 and the adjacent p-type trenches 124. Each of the n-type diffusion areas 150 is disposed on the adjacent first contact area 116 and the n-type trench 122. Each of the p-type diffusion areas 160 is disposed on the adjacent second contact area 118 and the p-type trench 124.

The solar cell 100 further includes a plurality of first conductive layers 170 and a plurality of second conductive layers 180. The first conductive layers 170 are disposed on the first contact areas 116 and are connected to a part of the n-type diffusion areas 150. The second conductive layers 180 are disposed on the second contact areas 118 and are connected to a part of the p-type diffusion areas 160. The first conductive layers 170 and the second conductive layers 180 are coplanarly arranged. The first and second conductive layers 170 and 180 are made of material with electrical conducting ability, such as transparent conducting oxides (TOO), or a thin metal layer. The transparent conducting oxides can be but not limited to ITO, IZO, AZO, GZO, or IMO. The thin metal layer can be made of Ag, Al, or alloy thereof.

The n-type diffusion areas 150 and the p-type diffusion areas 160 can be extended into the substrate 110 with the design of the trenches 120. The diffusion area of the n-type diffusion areas 150 and the p-type diffusion areas 160 can be increased, and the contact area of the n-type diffusion areas 150 and the p-type diffusion areas 160 relative to the electron-hole pair can be enlarged. Such that the when an electron-hole pair is generated, the electron or the hole can move toward the n-type diffusion areas 150 or the p-type diffusion areas 160 in a shorter path. The situation of the electron-hole pair recombination during movement or the electron or the hole being captured by a recombination center of the semiconductor substrate 110 can be prevented.

The depth d of the trenches 120 is equal to or greater than half of the thickness t of the substrate 110. The thickness t of the substrate 110 is about 165 μm to 200 μm. Each of the first contact areas 116 and each of the second contact areas 118 has the substantially same width w1. The width w1 of the first contact areas 116 and the second contact areas 118 is substantially not smaller than a width w2 of each of the trenches 120. The depth d, the width w2, and the density of the trenches 120 can be well designed in order not to damage the structure strength of the substrate 110.

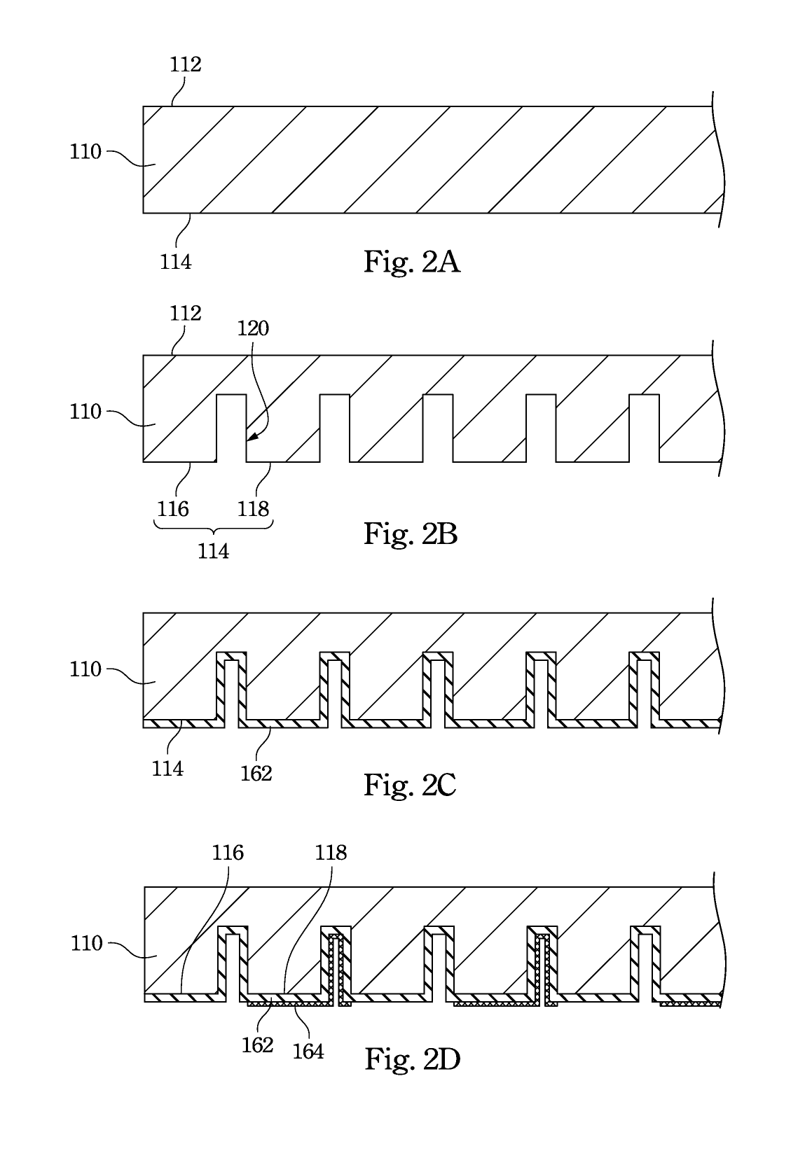

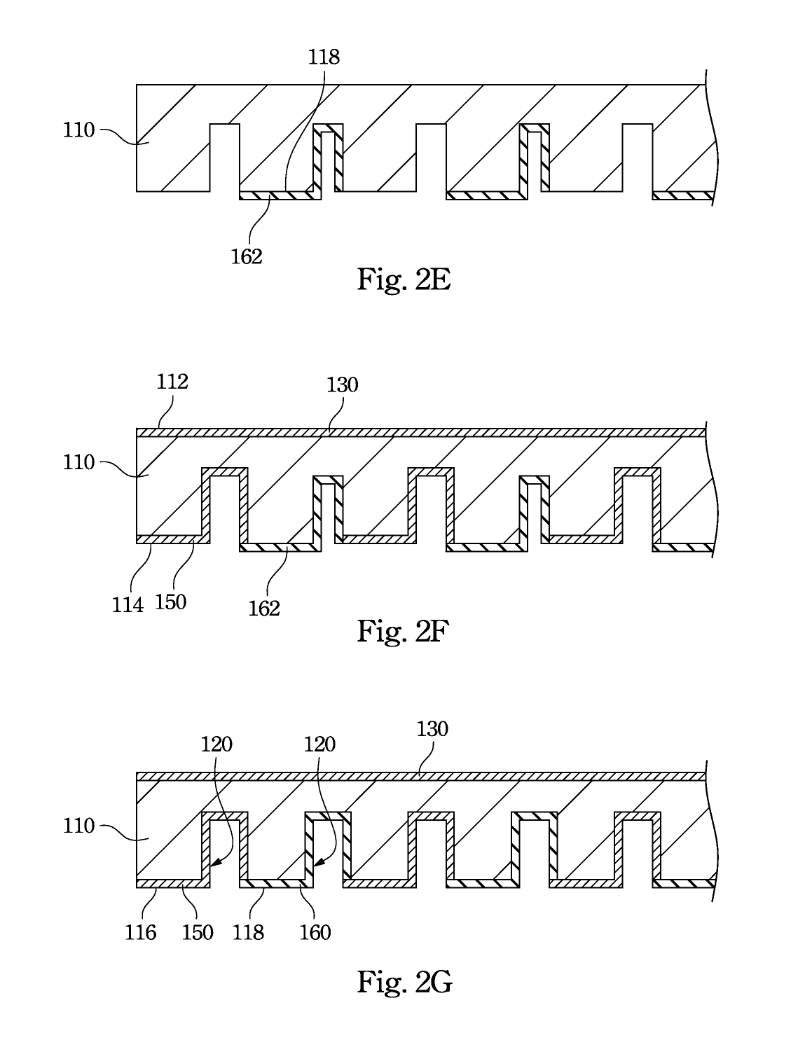

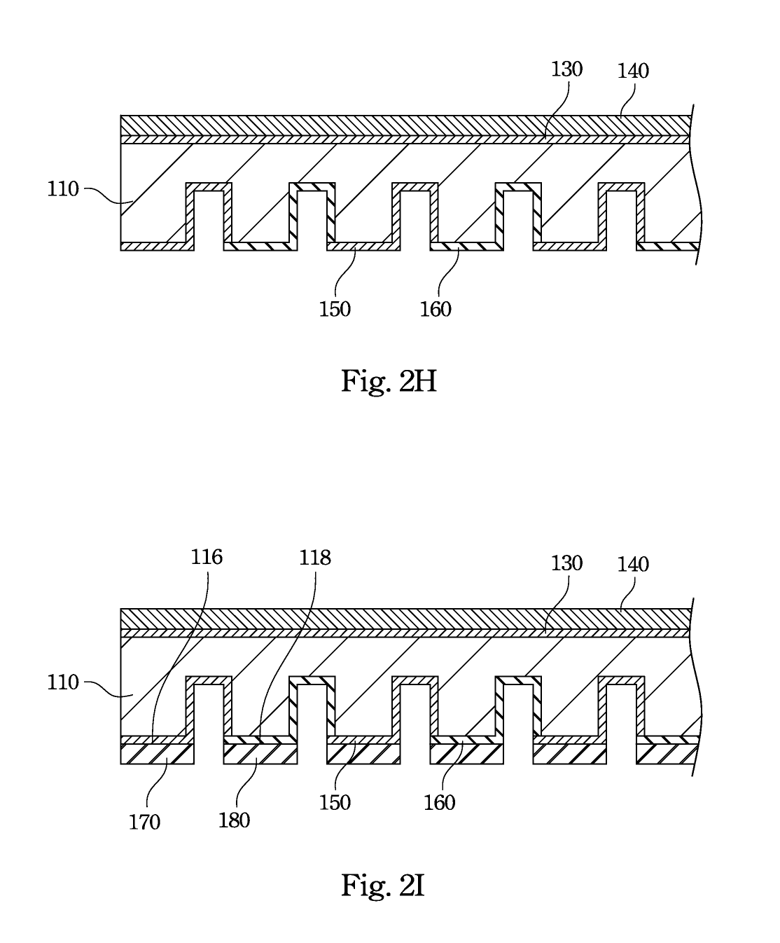

FIG. 2A to FIG. 2I are cross-sectional views of a solar cell of different steps of an embodiment of a method for fabricating solar cell of the invention. A substrate 110 is provided in FIG. 2A. The substrate 110 has a light-receiving surface 112 and a back surface 114 opposite to the light-receiving surface 112. The light-receiving surface 112 and the back surface 114 can be roughened in FIG. 2A.

In FIG. 2B, a plurality of trenches 120 are formed on the back surface 114 of the substrate 110. The trenches 120 divide the back surface 114 into a plurality of first contact areas 116 and a plurality of second contact areas 118. The first contact areas 116 and the second contact areas 118 are alternately arranged. The trenches 120 can be formed on the substrate 110 by a physical process, such as laser drilling, or by a chemical process, such as etching.

In FIG. 2C, a plurality of p-type material layers 162 are formed on the back surface 114 and the surface of the trenches 120. The p-type material layers 162 can be formed by an ion implantation process, such as a p-type ion doping or diffusing process. The p-type material layers 162 can be formed by a deposition process.

In FIG. 2D, a patterned mask 164 is formed on the p-type material layers 162 which are disposed on the second contact areas 118. The patterned mask 164 can be a patterned photo resist layer.

In FIG. 2E, an etching process is processed to remove a part of the p-type material layers 162 which are not covered by the mask 164. The etching process can be a wet etching process, in which the solution for etching can be alkaline solution, such as KOH solution or NaOH solution. Then the mask 164 can be removed.

In FIG. 2F, the substrate 110 is sent into an oven filled with n-type material gas, and the substrate 110 is heated in the oven. An n-type diffusion layer is formed on the light-receiving surface 112 as the front surface field 130. A plurality of n-type diffusion areas 150 are formed on a part of the back surface 114 which are not covered by the p-type material areas 162. The heating temperature of the oven is about 800° C. to 880° C.

In FIG. 2G, the temperature of the oven is raised again. The heating temperature of the oven is over 900° C., such that the p-type material layers 162 in FIG. 2F are diffused into the substrate 110 thereby forming a plurality of p-type diffusion areas 160. Accordingly, the n-type diffusion areas 150 are formed on the first contact areas 116 and a part of the trenches 120 which are disposed adjacent to a side of the first contact areas 116, and the p-type diffusion areas 160 are formed on the second contact areas 118 and another part of the trenches 120 which are disposed adjacent to a side of the second contact areas 118. The n-type diffusion areas 150 and the p-type diffusion areas 160 are alternately arranged. Then the substrate 110 is left the oven.

In FIG. 2F, an antireflection layer 140 is formed on the front surface field 140.

In FIG. 2I, a plurality of first conductive layers 170 are formed on the first contact areas 116, and a plurality of second conductive areas 180 are formed on the second contact areas 118.

According to above embodiment, the n-type diffusion areas and the p-type diffusion areas can be extended into the substrate with the design of the trenches. Such that the when an electron-hole pair is generated, the electron or the hole can move toward the n-type diffusion areas or the p-type diffusion areas in a shorter path. The situation of the electron-hole pair recombination during movement or the electron or the hole being captured by a recombination center of the semiconductor substrate can be prevented.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar cell comprising:
a substrate comprising:
a light-receiving surface;
a back surface opposite to the light-receiving surface; and
a plurality of trenches disposed on the back surface, wherein the trenches divide the back surface into a plurality of first contact areas and a plurality of second contact areas, and the first contact areas and the second contact areas are alternately arranged;
a front surface field disposed on the light-receiving surface of the substrate;
an antireflection layer disposed on the front surface field; and
a plurality of n-type diffusion areas and a plurality of p-type diffusion areas alternately disposed on the back surface, wherein the n-type diffusion areas are respectively disposed on a surface of the first contact areas and a part of the trenches connecting to a side of the first contact areas, and the p-type diffusion areas are respectively disposed on a surface of the second contact areas and another part of the trenches connecting to a side of the second contact areas.

2. The solar cell of claim 1, wherein a depth of the trenches is equal or larger than half of a thickness of the substrate.

3. The solar cell of claim 2, wherein a width of the first contact areas is substantially equal to a width of the second contact areas.

4. The solar cell of claim 3, wherein the width of the first contact areas and the second contact areas is substantially not smaller than a width of the trenches.

5. The solar cell of claim 1, further comprising a plurality of first conductive layers disposed on the first contact areas respectively, and a plurality of second conductive layers disposed on the second contact areas respectively, wherein the first conductive layers and the second conductive layers are arranged coplanarly.

6. The solar cell of claim 1, wherein the trenches are arranged parallel to each other.

7. The solar cell of claim 1, wherein the trenches are arranged vertically to the first contact areas and the second contact areas.

8. The solar cell of claim 1, wherein opposite sides of each of the first contact areas are respectively connected to a p-type trench and a n-type trench, and opposite sides of each of the first contact areas are respectively connected to the n-type trench and the p-type trench, wherein the p-type trench is the trench with p-type diffusion area thereon, and the n-type trench is the trench with n-type diffusion area thereon.

9. A method for fabricating solar cell, the method comprising:
providing a substrate, the substrate comprising a light-receiving surface and a back surface opposite to the light-receiving surface;
forming a plurality of trenches on the back surface of the substrate, wherein the trenches divide the back surface into a plurality of first contact areas and a plurality of second contact areas, and the first contact areas and the second contact areas are alternately arranged;
forming a plurality of n-type diffusion areas on a surface of the first contact areas and a part of the trenches connecting to a side of the first contact areas;
forming a plurality of p-type diffusion areas on a surface of the second contact areas and another part of the trenches connecting to a side of the second contact areas;
forming a front surface field on the light-receiving surface; and
forming an antireflection layer on the front surface field.

10. The method for fabricating solar cell of claim 9, wherein the trenches are formed on the back surface of the substrate by a laser drilling process or an etching process.

11. The method for fabricating solar cell of claim 9, wherein a depth of the trenches is equal to or greater than half of a thickness of the substrate.

12. The method for fabricating solar cell of claim 11, wherein a width of the first contact areas is substantially equal to a width of the second contact areas.

13. The method for fabricating solar cell of claim 12, wherein the width of the first contact areas and the second contact areas is substantially not smaller than a width of the trenches.

14. The method for fabricating solar cell of claim 9, further comprising:
to forming a plurality of first conductive areas on the first conduct areas respectively; and
forming a plurality of second conductive areas on the second conductive areas respectively, wherein the first conductive areas and the second conductive areas are arranged coplanarly.

15. The method for fabricating solar cell of claim 9, wherein the trenches are arranged parallel to each other.

16. The method for fabricating solar cell of claim 9, wherein the trenches are arranged vertically to the first contact areas and the second contact areas.

17. The method for fabricating solar cell of claim 9, wherein opposite sides of each of the first contact areas are respectively connected to a p-type trench and a n-type trench, and opposite sides of each of the first contact areas are respectively connected to the n-type trench and the p-type trench, wherein the p-type trench is the trench with p-type diffusion area thereon, and the n-type trench is the trench with n-type diffusion area thereon.
